(19) United States
(12) Patent Application Publication
(10) Pub. No.: US 2024/0200989 A1
(43) Pub. Date: Jun. 20, 2024

(54) SENSOR ASSEMBLY

(71) Applicant: Ford Global Technologies, LLC, Dearborn, MI (US)

(72) Inventors: Rashaun Phinisee, Ypsilanti, MI (US); Venkatesh Krishnan, Canton, MI (US); Michael Robertson, JR., Garden City, MI (US)

(73) Assignee: Ford Global Technologies, LLC, Dearborn, MI (US)

(21) Appl. No.: 18/067,754

(22) Filed: Dec. 19, 2022

(51) Int. Cl. G01D 11/24; B60S 1/56; G02B 27/00

(52) U.S. Cl. CPC G01D 11/245; B60S 1/56; G02B 27/0006; G01S 7/4813

(57) ABSTRACT

An assembly includes a beam having a front panel and a rear panel spaced from the front panel. The beam defines a duct between the front panel and the rear panel. The assembly includes a sensor supported by the beam, the sensor having a sensor window adjacent the front panel and a plurality of fins adjacent the rear panel. The assembly includes a nozzle supported by the front panel and positioned to direct airflow toward the sensor window of the sensor. The assembly includes an outlet defined by the rear panel and shaped to direct airflow toward the fins of the sensor. The assembly includes a blower in fluid communication with the nozzle and the outlet through the duct.

### BACKGROUND

Vehicles typically include sensors. The sensors can provide data about operation of the vehicle, for example, wheel speed, wheel orientation, and engine and transmission data (e.g., temperature, fuel consumption, etc.). The sensors can detect the location and/or orientation of the vehicle. The sensors can be global positioning system (GPS) sensors; accelerometers such as piezo-electric or microelectromechanical systems (MEMS); gyroscopes such as rate, ring laser, or fiber-optic gyroscopes; inertial measurements units (IMU); and/or magnetometers. The sensors can detect the external world, e.g., objects and/or characteristics of surroundings of the vehicle, such as other vehicles, road lane markings, traffic lights and/or signs, pedestrians, etc. For example, the sensors can be radar sensors, scanning laser range finders, light detection and ranging (LIDAR) devices, and/or image processing sensors such as cameras.

### BRIEF DESCRIPTION OF THE DRAWINGS

FIG. 1 is a perspective view of a vehicle having a sensor assembly supported by a roof of the vehicle.

FIG. 2 is a perspective view of the sensor assembly.

FIG. 3 is a perspective view of the sensor assembly having a frontal portion exploded for illustration.

FIG. 4 is a frontal view of a portion of the sensor assembly.

FIG. 5 is a perspective view of the portion of the sensor assembly.

FIG. 6 is a top cross-sectional view of the portion of the sensor assembly.

### DETAILED DESCRIPTION

An assembly includes a beam having a front panel and a rear panel spaced from the front panel. The beam defines a duct between the front panel and the rear panel. The assembly includes a sensor supported by the beam, the sensor having a sensor window adjacent the front panel and a plurality of fins adjacent the rear panel. The assembly includes a nozzle supported by the front panel and positioned to direct airflow toward the sensor window of the sensor. The assembly includes an outlet defined by the rear panel and shaped to direct airflow toward the fins of the sensor. The assembly includes a blower in fluid communication with the nozzle and the outlet through the duct.

The sensor may be a first sensor. The assembly may include a second sensor supported by the beam. The second sensor may have a second sensor window adjacent the front panel and a plurality of fins adjacent the rear panel.

The assembly may include a third sensor between the first sensor and the second sensor along a length of the beam.

The sensor window may be a first sensor window and the third sensor may have a third sensor window. The assembly may include a second nozzle supported by the beam and positioned to direct airflow toward the third sensor window of the third sensor.

The third sensor may be supported by the front panel of the beam.

The front panel of the beam may define a second outlet adjacent the third sensor, the blower being in fluid communication with the second outlet.

The assembly may include a second nozzle supported by the front panel and positioned to direct airflow toward the second sensor window of the second sensor and a second outlet defined by the rear panel and shaped to direct airflow toward the fins of the second sensor.

The duct may be elongated from the first sensor to the second sensor.

The beam may be elongated along a cross-vehicle axis.

The nozzle may include a first portion elongated transverse to the beam and a second portion elongated parallel to the beam.

The nozzle may define a flow path across the sensor window.

The outlet may define a flow path across the fins.

The nozzle may be between the sensor window and the beam along a length of the beam.

The assembly may include a deflector supported by the rear panel. The deflector may be adjacent the outlet.

The deflector may include a first portion elongated transverse to the beam and a second portion elongated parallel to the beam.

The deflector may be shaped to direct airflow from the outlet and over the fins.

The outlet may define a flow path along the deflector and across the fins of the sensor.

The beam may be elongated from a first end to a second end, the sensor being supported at the first end of the beam.

The assembly may include a second sensor supported at the second end of the beam.

The duct may be elongated from the first end to the second end.

With reference to the Figures, wherein like numerals indicate like parts throughout the several views, an assembly 10 for a vehicle 12 including a beam 14 having a front panel 16 and a rear panel 18 spaced from the front panel 16. The beam 14 defines a duct 20 between the front panel 16 and the rear panel 18. The assembly 10 includes a sensor 22 supported by the beam 14, the sensor 22 having a sensor window 24 adjacent the front panel 16 and a plurality of fins 26 adjacent the rear panel 18. The assembly 10 includes a nozzle 28 supported by the front panel 16 and positioned to direct airflow toward the sensor window 24 of the sensor 22. The assembly 10 includes an outlet 30 defined by the rear panel 18 and shaped to direct airflow toward the fins 26 of the sensor 22. The assembly 10 includes a blower 32 in fluid communication with the nozzle 28 and the outlet 30 through the duct 20.

The blower 32 pressurizes the duct 20 to allow air to move through the nozzle 28 and the outlet 30 to cool and clean the sensor 22 supported by the beam 14. The nozzle 28 directs the air from the blower 32 over the sensor window 24 to remove debris from the sensor window 24. The outlet 30 directs air over the fins 26 to aid in cooling of the sensor 22 during use. The combination of the nozzle 28 and the outlet 30 allow for both the cooling and the cleaning to occur simultaneously and from a single source of airflow.

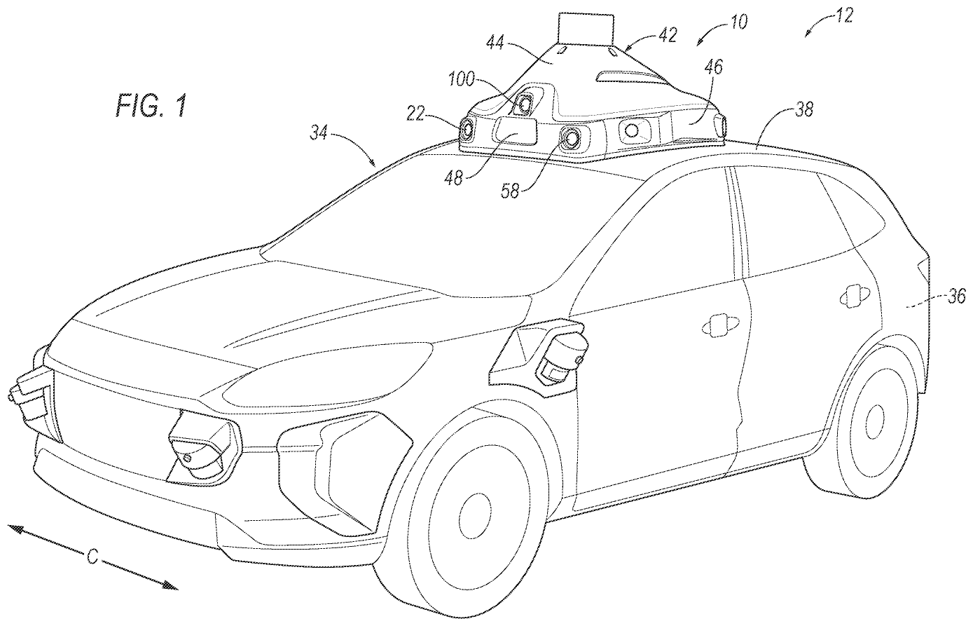

With reference to FIG. 1, the vehicle 12 may be any passenger or commercial automobile such as a car, a truck, a sport utility vehicle, a crossover, a van, a minivan, a taxi, a bus, etc.

The vehicle 12 includes a body 34. The vehicle 12 may be of a unibody construction, in which a frame 36 and the body 34 of the vehicle 12 are a single component. The vehicle 12 may, alternatively, be of a body-on-frame construction, in which the frame 36 supports the body 34 that is a separate component from the frame 36. The frame 36 and body 34 may be formed of any suitable material, for example, steel, aluminum, etc.

The body 34 of the vehicle 12 includes a roof 38. The roof 38 may be the upper boundary of the vehicle 12, e.g., of a passenger compartment that houses occupants of the vehicle 12. The roof 38 may define a class-A surface. A class-A surface is a finished surface exposed to view by a customer and free of unaesthetic blemishes and defects.

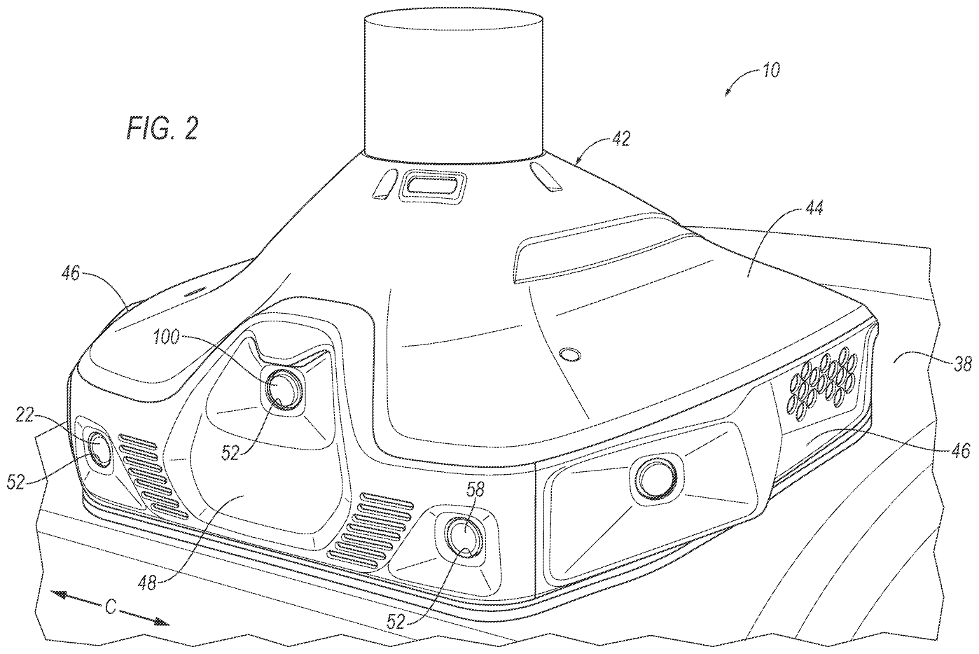

With reference to FIGS. 1 and 2, the vehicle 12 includes the assembly 10, hereinafter referred to as the sensor assembly 10, supported by the roof 38 of the vehicle 12. The sensor assembly 10 may be mounted to the roof 38. For example, the sensor assembly 10 may be mounted to the roof 38 in any suitable way, e.g., fasteners, adhesive, welding, etc. As further discussed below, the sensor assembly 10 may include a plurality of sensors 22, 58, 60, 100 to perceive the external world around the vehicle 12 and a plurality of other internal components, including the beam 14, blowers, pressurized compartments, inlets, outlets, electrical components, wiring, etc. The sensors 22, 58, 60, 100 of the sensor assembly 10 may work together to perceive the external world around the vehicle 12.

The sensor assembly 10 includes a housing 42. The housing 42 conceals internal components of the sensor assembly 10. In other words, the housing 42 may seal the internal components from the outside world.

The housing 42 may include one or more portions. For example, the housing 42 includes an upper portion 44, two side portions 46, and a frontal portion 48. The upper portion 44 may be spaced upwardly from the roof 38 of the vehicle 12. The side portions 46 may face sides of the vehicle 12 and be spaced cross-vehicle from each other. The frontal portion 48 may face a front of the vehicle 12, i.e., when the vehicle 12 is moving in a forward direction. The portions may be attached to each other or other internal components concealed by the housing 42. For example, the portions may be attached in any suitable way, e.g., by fasteners, snapping features, etc.

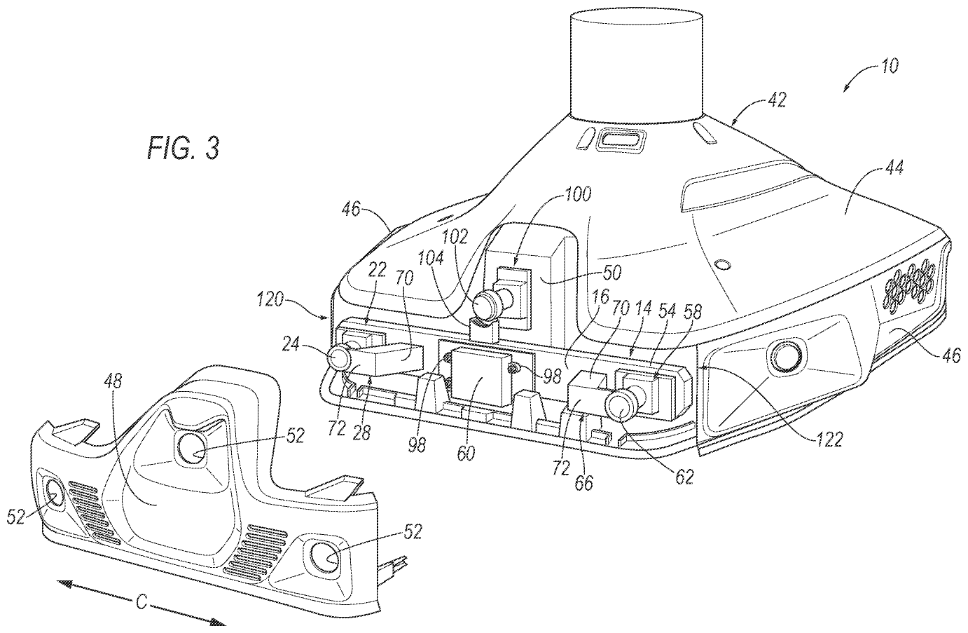

With reference to FIG. 3, the housing 42 may include internal portions that support the housing 42 against the roof 38. For example, the housing 42 includes an internal support wall 50 extending upwardly from the roof 38. The beam 14 may be supported by the internal support wall 50 of the housing 42.

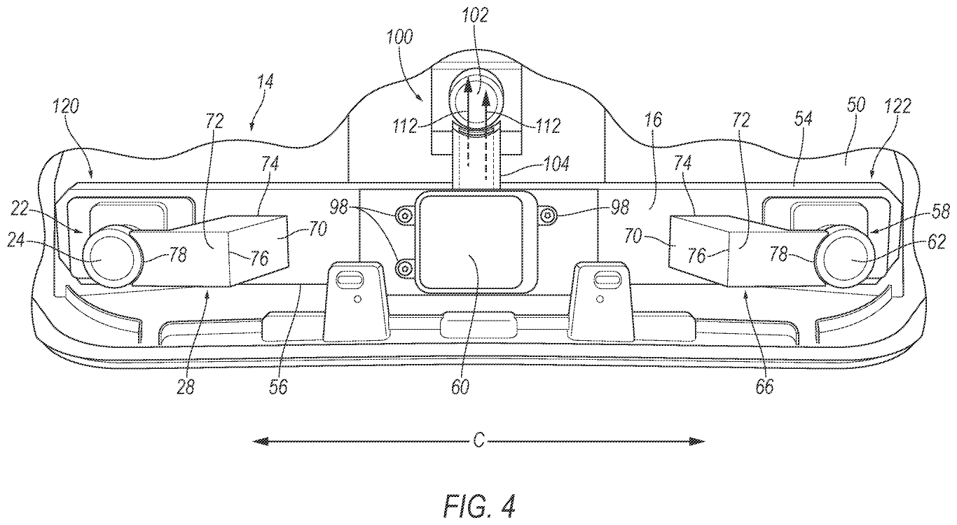

With reference to FIGS. 3 and 4, the beam 14 may be supported by the internal support wall 50 and face vehicle-forward, i.e., toward a front of the vehicle 12. The beam 14 may be mounted to the internal support wall 50. The beam 14 may be mounted to the internal support wall 50. In other words, the beam 14 may be mounted in such a way that the beam 14 remains stationary relative to the remainder of the sensor assembly 10. The beam 14 may be mounted to the internal support wall 50 in any suitable way, e.g., fasteners, welding, adhesive, etc.

The frontal portion 48 of the housing 42 may conceal the beam 14. In other words, the beam 14 may be between the frontal portion 48 of the housing 42 and the internal support wall 50. The frontal portion 48 may define holes 52 for sensors 22, 58, 100 to be directed toward. In other words, the sensors 22, 58, 60, 100 may have a field of view through the holes 52 of the frontal portion 48.

The beam 14 may be elongated along a cross-vehicle axis C. The beam 14 may be elongated along the cross-vehicle axis C from a first end 120 to a second end 122. The beam 14 includes a front panel 16, a rear panel 18, a top panel 54, and a bottom panel 56. The rear panel 18 is spaced from the front panel 16. The rear panel 18 may be spaced vehicle-rearward of the front panel 16. The front panel 16 may face vehicle-forward and the rear panel 18 may face vehicle-rearward. The top panel 54 may be spaced from the bottom panel 56. The top panel 54 may be spaced upwardly from the bottom panel 56. The front panel 16 may be spaced from the rear panel 18 by the top panel 54 and the bottom panel 56.

The beam 14 defines the duct 20 between the front panel 16 and the rear panel 18. The beam 14 defines the panel between the top panel 54 and the bottom panel 56. The duct 20 is elongated from the first end 120 to the second end 122. In other words, the duct 20 runs the length of the beam 14.

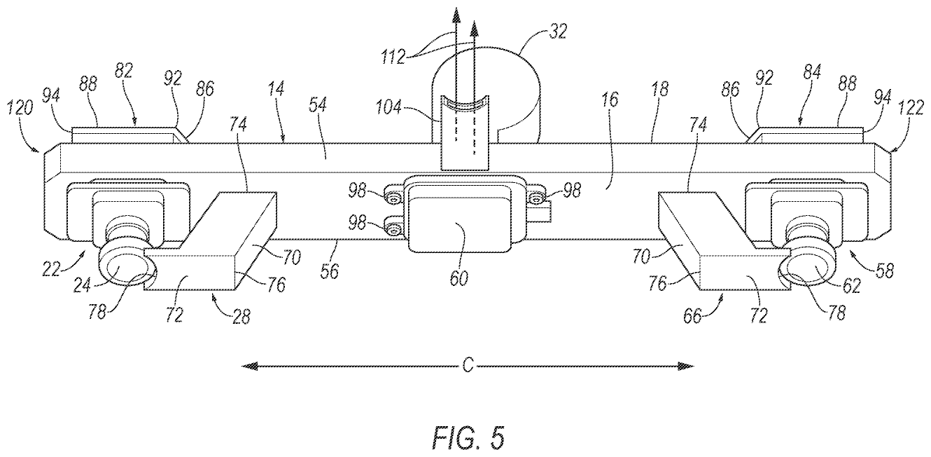

With reference to FIGS. 3-6, the sensor assembly 10 may include one or more sensors 22, 58, 60 supported by the beam 14. For example, and as described further below, three sensors 22, 58, 60, a first sensor 22, a second sensor 58, and a third sensor 60, are supported by the beam 14 at various locations along the beam 14. The sensor assembly 10 may include a fourth sensor 100 supported by the internal support wall 50 above the beam 14. The sensor assembly 10 may include more sensors 22, 58, 60, 100 other than the first sensor 22, the second sensor 58, the third sensor 60, and the fourth sensor 100 supported by other components and at other locations of the housing 42.

The first sensor 22, the second sensor 58, the third sensor 60, and the fourth sensor 100 may detect the external world, e.g., objects and/or characteristics of surroundings of the vehicle 12, such as other vehicles, road lane markings, traffic lights and/or signs, pedestrians, etc. For example, the sensors 22, 58, 60, 100 may be radar sensors, ultrasonic sensors, scanning laser range finders, light detection and ranging (LIDAR) devices, image processing sensors such as cameras, etc. In the example shown in the Figures, the first sensor 22, the second sensor 58, and the fourth sensor 100 may be cameras and may detect electromagnetic radiation in some range of wavelengths. For example, the first sensor 22, the second sensor 58, and the fourth sensor 100 may detect visible light, infrared radiation, ultraviolet light, or some range of wavelengths including visible, infrared, and/or ultraviolet light. For example, the cameras may be a charge-coupled devices (CCD), complementary metal oxide semiconductors (CMOS), or any other suitable type. The first sensor 22, the second sensor 58, and the fourth sensor 100 may include sensor lenses. In the example shown in the Figures, the third sensor 60 may be a radar sensor. The third sensor 60 may be attached to the beam 14 by one or more fasteners 98 to allow the third sensor 60 to remain stationary.

The first sensor 22, the second sensor 58, and the fourth sensor 100 each include a sensor window 24, 60, 102 and a set of fins 26, 64. For example, the first sensor 22 includes a first sensor window 24 and a first set of fins 26 opposite the first sensor window 24, the second sensor 58 includes a second sensor window 62 and a second set of fins 64 opposite the second sensor window 62, and the fourth sensor 100 includes a third sensor window 102 and third set of fins (not shown or numbered). The first sensor window 24, the second sensor window 62, and the third sensor window 102 are oriented to have fields of view of the external environment around the vehicle 12. The fields of view of the first sensor 22, the second sensor 58, and the fourth sensor 100 may extend through the first sensor window 24, the second sensor window 62, and the third sensor window 102. For example, when the first sensor 22, the second sensor 58, and the fourth sensor 100 are cameras, the first sensor window 24, the second sensor window 62, and the third sensor 60 may be lenses.

The first set of fins 26, the second set of fins 64, and the third set of fins may extend outwardly from a back side of the first sensor 22, the second sensor 58, and the fourth sensor 100, respectively. The sets of fins 26, 64 may allow for the cooling of the first sensor 22 and the second sensor 58 when the sensors 22, 58, 60, 100 are in use. The sets of fins 26, 64 may be of any suitable material, for example, a heat conductive material, to draw heat away from a body (not numbered) of the sensor to cool the sensor. In other words, the sets of fins 26, 64 may have a high thermal conductivity, e.g., a thermal conductivity equal to at least 15 watts per meter-Kelvin (W/(m K)), e.g., greater than 100 W/(m K), at 25° C. For example, the sets of fins 26, 64 may be aluminum. As the heat is drawn away from the body of the sensor, ambient air or, in the example explained further below, forced air, may pass over the sets of fins 26, 64 to allow for convection cooling to occur.

The first sensor 22 and the second sensor 58 are each supported by the beam 14. The first sensor 22 and the second sensor 58 are spaced from each other along the beam 14, i.e., along a length of the beam 14. The first sensor 22 is supported by the first end 120 of the beam 14 and the second sensor 58 is supported by the second end 122 of the beam 14. In other words, the first sensor 22 and the second sensor 58 are spaced from each other along the cross-vehicle axis C. The first sensor 22 and the second sensor 58 may be mounted to the beam 14. The first sensor 22 and second sensor 58 may each extend through the beam 14 to be mounted by the beam 14. The first sensor 22 and the second sensor 58 may be mounted to the beam 14 in any suitable way. For example, the first sensor 22 and second sensor 58 may include snap features, fasteners, etc. to mount the sensors 22, 58 to the beam 14.

As the first sensor 22 and second sensor 58 extend through the beam 14, the first sensor window 24 and the second sensor window 62 are adjacent the front panel 16 of the beam 14 and the sets of fins 26, 64 are adjacent the rear panel 18. In other words, the first set of fins 26 and the second set of fins 64 extend from a back side of the beam 14 while the first sensor window 24 and second sensor window 62 extend from a front side of the beam 14.

As discussed above, the beam 14 defines the duct 20 elongated from the first end 120 to the second end 122. In particular, the duct 20 is elongated from the first sensor 22 to the second sensor 58. In other words, the duct 20 may extend from the first sensor 22 to the second sensor 58.

The first sensor window 24 and the second sensor window 62 are supported by the beam 14 in locations such that the first sensor window 24 and the second sensor window 62 each align with a hole 52 in the frontal portion 48 of the housing 42. The field of view of the first sensor window 24 and the second sensor window 62 may be through the holes 52 of the frontal portion 48 of the housing 42.

With continued reference to FIGS. 3-6, the sensor assembly 10 includes one or more nozzles 28, 66 supported by the front panel 16 of the beam 14. For example, as shown in the Figures, the sensor assembly 10 includes a first nozzle 28 supported by the front panel 16 adjacent the first end 120 of the beam 14 and a second nozzle 66 supported by the front panel 16 adjacent the second end 122 of the beam 14. The first nozzle 28 may be supported adjacent the first sensor 22 and the second nozzle 66 may be supported adjacent the second sensor 58. The first nozzle 28 is positioned adjacent the first sensor 22 to direct airflow toward the first sensor window 24 of the first sensor 22. The second nozzle 66 is positioned adjacent the second sensor 58 to direct airflow toward the second sensor window 62 of the second sensor 58. The first nozzle 28 and the second nozzle 66 are both between the first sensor 22 and the second sensor 58. In other words, the first nozzle 28 and the second nozzle 66 are between the first sensor window 24 and the second sensor window 62 along a length of the beam 14. Both the first nozzle 28 and the second nozzle 66 may each define a channel 124 that allows airflow to pass through the nozzles 28, 66 and directs the airflow at the first sensor window 24 and the second sensor window 62. In other words, each of the first nozzle 28 and the second nozzle 66 is hollow to allow airflow to move through the first nozzle 28 and the second nozzle 66. The first nozzle 28 and the second nozzle 66 may be directed toward the first sensor window 24 and the second sensor window 62 to remove debris from the first sensor window 24 and the second sensor window 62, e.g., liquid, dirt, insects, etc.

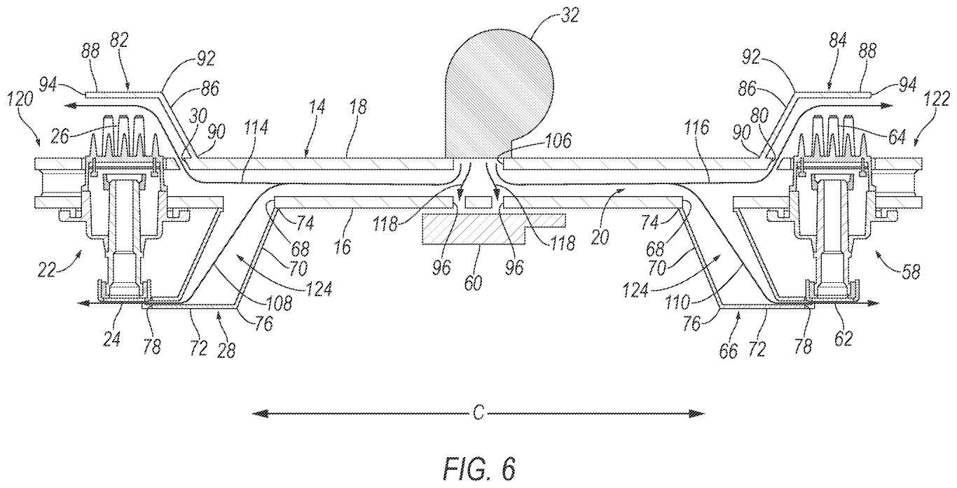

With reference to FIG. 6, the front panel 16 of the beam 14 defines a pair of openings 68, a first opening 68 adjacent the first sensor 22 and a second opening 68 adjacent the second sensor 58. The first opening 68 may be aligned with the first nozzle 28 and the second opening 68 may be aligned with the second nozzle 66. The channels 124 of the first nozzle 28 and the second nozzle 66 are aligned with the openings 68 of the front panel 16 of the beam 14. The nozzles 28, 66 being aligned with the openings 68 allows airflow to pass through the openings 68 and through the channels 124.

The first nozzle 28 and the second nozzle 66 each include a first nozzle portion 70 that is elongated transverse to the beam 14. The first nozzle 28 and the second nozzle 66 each include a second nozzle portion 72 elongated parallel to the beam 14. In other words, the first nozzle portion 70 is elongated at an angle relative to the beam 14 and the second nozzle portion 72 is elongated along the beam 14. The second nozzle portion 72 may be spaced from the beam 14 by the first nozzle portion 70. The first nozzle portions 70 of the nozzles 28, 66 extend from a nozzle proximal end 74 to a channel corner 76. The first nozzle portions 70 may each be elongated from the nozzle proximal end 74 to the channel corner 76 in a direction that is vehicle-forward and vehicle-outboard, i.e., away from the beam 14 and toward the respective first end 120 or second end 122. The second nozzle portion 72 is elongated from the channel corner 76 to a nozzle distal end 78. The nozzle distal ends 78 of each of the nozzles 28, 66 is adjacent the first sensor window 24 and the second sensor window 62. The nozzle distal ends 78 of each of the nozzles 28, 66 each act as outlets (not numbered) to allow air to move across the sensor windows 24, 62. The channel 124 of the nozzles 28, 66 may turn at the channel corner 76 of the nozzles 28, 66 toward the nozzle distal end 78. Air may pass through the beam 14, along the channel 124 and out the nozzle distal end 78 to move air across the sensor windows 24, 62.

The rear panel 18 of the beam 14 may define one or more outlets 30, 80. For example, the rear panel 18 defines a first outlet 30 adjacent the first sensor 22 and a second outlet 80 adjacent the second sensor 58. The first outlet 30 is adjacent the first set of fins 26 of the first sensor 22 and the second outlet 80 is adjacent the second set of fins 64 of the second sensor 58. The outlets 30, 80 are positioned to direct airflow over the fins 26, 64 of each of the sensors 22, 58. For example, the outlets 30, 80 are shaped to direct airflow toward the fins 26, 64 of the sensors 22, 58. The outlets 30, 80 may be angled to allow airflow to pass over the fins 26, 64 when airflow passes through the outlets 30, 80. The first outlet 30 and the second outlet 80 may be directed toward the first set of fins 26 and the second set of fins 64 to allow the fins 26, 64 to be cooled during use of the sensors 22, 58.

The sensor assembly 10 may include one or more deflectors 82, 84 supported by the rear panel 18 of the beam 14. The sensor assembly 10 may include one or more deflectors 82, 84 adjacent the sensors 22, 58 and supported by the rear panel 18. For example, the sensor assembly 10 may include a first deflector 82 adjacent the first sensor 22 and a second deflector 84 adjacent the second sensor 58. The first deflector 82 and the second deflector 84 may extend off a back side of the beam 14, i.e., the rear panel 18. The deflectors 82, 84 may be positioned and shaped to direct airflow over the sensors 22, 58. For example the deflectors 82, 84 may be positioned and shaped to direct airflow over the fins 26, 64 of the sensors 22, 58. The first deflector 82 may direct airflow over the first set of fins 26 and the second deflector 84 may direct airflow over the second set of fins 64.

The first deflector 82 may be adjacent the first outlet 30 and the second deflector 84 may be adjacent the second outlet 80. As shown in FIG. 6, the first outlet 30 may be between the first deflector 82 and the first sensor 22 and the second outlet 80 may be between the second deflector 84 and the second sensor 58. The deflectors 82, 84 are shaped to direct airflow from the outlets 30, 80 and over the fins 26, 64 of the sensors 22, 58. As airflow moves through the outlets 30, 80, the deflectors 82, 84 may direct the airflow over the fins 26, 64 of each of the sensors 22, 58.

The deflectors 82, 84 include a first deflector portion 86 elongated transverse to the beam 14. In other words, the first deflector portion 86 extends at an angle from the rear panel 18 of the beam 14. The first deflector portion 86 extends from a deflector proximal end 90 to a deflector corner 92. The deflectors 82, 84 include a second deflector portion 88 elongated parallel to the beam 14 to a deflector distal end 94. The second deflector portion 88 is elongated from the deflector corner 92 to deflector distal ends 94. The second deflector portion 88 may be spaced from the beam 14 and spaced from the fins 26, 64 of the sensors 22, 58 to allow airflow to pass over the fins 26, 64 of the sensors 22, 58.

As discussed above, the third sensor 60 may be supported by the front panel 16 of the beam 14. The front panel 16 of the beam 14 may define a second pair of outlets 96 adjacent the third sensor 60. The second pair of outlets 96 may be spaced from each other along the length of the beam 14 to allow airflow to exit the duct 20 and flow over the third sensor 60. The second pair of outlets 96 may be directed toward the third sensor 60 to cool the third sensor 60 during use.

As discussed above, the fourth sensor 100 may be supported above the beam 14. For example, the fourth sensor 100 may be supported by the internal support wall 50 of the housing 42. The third sensor window 102 of the fourth sensor 100 is position to be aligned with a hole 52 in the frontal portion 48 of the housing 42. The sensor assembly 10 may include a third nozzle 104 directed toward the fourth sensor 100. The third nozzle 104 may be supported by the top panel 54 of the beam 14. The third nozzle 104 is shaped and positioned to direct airflow toward the third sensor window 102. The third nozzle 104 extend upwardly from the top panel 54 toward the third sensor window 102.

The sensor assembly 10 includes at least one blower 32 in fluid communication with the nozzles 28, 66 and outlets 30, 80, 96. For example, the sensor assembly 10 includes one blower 32 connected to the rear panel 18. The rear panel 18 defines an inlet 106 to allow the blower 32 to be in fluid communication with the nozzles 28, 66 and the outlets 30, 80, 96. The blower 32 may force air through the inlet 106 and into the duct 20 to pressurize the duct 20. The blower 32 is in fluid communication with the nozzles 28, 66 and the outlets 30, 80, 96 through the duct 20. As the air moves through the duct 20, the air may move out the outlets 30, 80, 96 and nozzles 28, 66 to cool and clean the sensors 22, 58, 60, 100. The sensor assembly 10 may include any suitable number of blowers 30 to pressurize the duct 20 of the beam 14.

With continued reference to FIG. 6, as the blower 32 moves air into the duct 20 and through the nozzles 28, 66 and outlets 30, 80, 96, the nozzles 28, 66 and outlets 30, 80, 96 define a plurality of flow paths through the nozzles 28, 66 and outlets 30, 80, 96. The air moved by the blower 32 may be separated into the plurality of flow paths to clean and cool the sensors 22, 58, 60, 100. The air moved by the blower 32 may split into the plurality of flow paths. The first nozzle 28 defines a first flow path 108 across the first sensor window 24. In other words, the blower 32 moves air into the duct 20 and air moves through the channel 124 of the first nozzle 28 and out the distal end of the first nozzle 28 toward the first sensor window 24. The air moving through the first nozzle 28 may clean the first sensor window 24 of debris. The second nozzle 66 defines a second flow path 110 across the second sensor window 62. In other words, the blower 32 moves air into the duct 20 and air moves through the channel 124 of the second nozzle 66 and out the distal end of the first nozzle 28 toward the second sensor window 62. The third nozzle 104 defines a third flow path 112 across the third sensor window 102. In other words, the blower 32 moves air into the duct 20 and through the third nozzle 104 toward and across the third sensor window 102. The first outlet 30 defines a fourth flow path 114 across the first set of fins 26. In other words, the blower 32 moves air into the duct 20 and air moves through the first outlet 30 across the first set of fins 26. The first deflector 82 may direct the air as the air moves out of the first outlet 30 to cool the first set of fins 26. The second outlet 80 defines a fifth flow path 116 across the second set of fins 64. In other words, the blower 32 moves air into the duct 20 and air moves through the second outlet 80 and across the second set of fins 64. The second deflector 84 may direct the air as the air moves of the second outlet 80 to cool the second set of fins 64. The second pair of outlets 96 in the front panel 16 define a sixth flow path 118 toward the third sensor 60. In other words, the blower 32 moves air into the duct 20 and through the second pair of outlets 96 to cool the third sensor 60.

The disclosure has been described in an illustrative manner, and it is to be understood that the terminology which has been used is intended to be in the nature of words of description rather than of limitation. The adjectives “first,” “second,” “third,” “fourth,” “fifth,” and “sixth” are used throughout this document as identifiers and are not intended to signify importance, order, or quantity. Many modifications and variations of the present disclosure are possible in light of the above teachings, and the disclosure may be practiced otherwise than as specifically described.

What is claimed is:

1. An assembly comprising:
a beam having a front panel and a rear panel spaced from the front panel;
the beam defining a duct between the front panel and the rear panel;
a sensor supported by the beam, the sensor having a sensor window adjacent the front panel and a plurality of fins adjacent the rear panel;
a nozzle supported by the front panel and positioned to direct airflow toward the sensor window of the sensor;
an outlet defined by the rear panel and shaped to direct airflow toward the fins of the sensor; and
a blower in fluid communication with the nozzle and the outlet through the duct.

2. The assembly of claim 1, wherein the sensor is a first sensor, the assembly further comprising a second sensor supported by the beam, the second sensor having a second sensor window adjacent the front panel and a plurality of fins adjacent the rear panel.

3. The assembly of claim 2, further comprising a third sensor between the first sensor and the second sensor along a length of the beam.

4. The assembly of claim 3, wherein the sensor window is a first sensor window, and the third sensor has a third sensor window, the assembly further comprising a second nozzle supported by the beam and positioned to direct airflow toward the third sensor window of the third sensor.

5. The assembly of claim 3, wherein the third sensor is supported by the front panel of the beam.

6. The assembly of claim 5, wherein the front panel of the beam defines a second outlet adjacent the third sensor, the blower being in fluid communication with the second outlet.

7. The assembly of claim 2, further comprising:
a second nozzle supported by the front panel and positioned to direct airflow toward the second sensor window of the second sensor; and
a second outlet defined by the rear panel and shaped to direct airflow toward the fins of the second sensor.

8. The assembly of claim 2, wherein the duct is elongated from the first sensor to the second sensor.

9. The assembly of claim 1, wherein the beam is elongated along a cross-vehicle axis.

10. The assembly of claim 1, wherein the nozzle includes a first portion elongated transverse to the beam and a second portion elongated parallel to the beam.

11. The assembly of claim 1, wherein the nozzle defines a flow path across the sensor window.

12. The assembly of claim 1, wherein the outlet defines a flow path across the fins.

13. The assembly of claim 1, wherein the nozzle is between the sensor window and the beam along a length of the beam.

14. The assembly of claim 1, further comprising a deflector supported by the rear panel, the deflector being adjacent the outlet.

15. The assembly of claim 14, wherein the deflector includes a first portion elongated transverse to the beam and a second portion elongated parallel to the beam.

16. The assembly of claim 14, wherein the deflector is shaped to direct airflow from the outlet and over the fins.

17. The assembly of claim 14, wherein the outlet defines a flow path along the deflector and across the fins of the sensor.

18. The assembly of claim 1, wherein the beam is elongated from a first end to a second end, the sensor being supported at the first end of the beam.

19. The assembly of claim 18, further comprising a second sensor supported at the second end of the beam.

20. The assembly of claim 18, wherein the duct is elongated from the first end to the second end.
